(19) United States
(12) Patent Application Publication
(10) Pub. No.: US 2005/0012489 A1
(43) Pub. Date: Jan. 20, 2005

(54) High frequency pulse width modulation

(75) Inventor: Chak Chakir, Austin, TX (US)

Correspondence Address: FORTKORT GRETHER + KELTON LLP, 8911 N. CAPITAL OF TEXAS HWY., SUITE 3200, AUSTIN, TX, 78759, US

(73) Assignee: JMC Products d/b/a LJM Products, Inc.

(21) Appl. No.: 10/621,029

(22) Filed: Jul. 16, 2003

(51) Int. Cl. H03C 1/06

(52) U.S. Cl. 318/801

(57) ABSTRACT

An electronic device is provided that achieves a reduction in the amount of unwanted noise produced as a consequence of electrical switching associated with pulse width modulation. The electrical device includes pulse width modulation controls for providing a plurality of settings for operation of the device. The electrical device includes a system for selectively controlling the frequency of the pulse width modulation to provide a desired output operational intensity in response to a known input signal. The system includes a high frequency pulse width modulation signal module adapted to provide frequencies above the audible range of anticipated users of the device, thereby reducing or eliminating the production of unwanted noise associated with the operation of such an electrical device.

Any references cited hereafter are incorporated by reference to the maximum extent allowable by law. To the extent a reference may not be fully incorporated herein, it is incorporated by reference for background purposes and indicative of the knowledge of one of ordinary skill in the art.

### BACKGROUND OF THE INVENTION

1. Field of the Invention

The present invention relates generally to the field of noise reduction.

2. Description of Related Art

Excess and unwanted noise has become a problem throughout much of society. Unwanted noise is often found to be distracting, thereby preventing people from giving their full concentration to tasks on which they attempt to keep their attention.

For example, a person attempting to give full attention to soft sounds such as the soft sounds associated with a quiet scene in a movie would find himself hindered in that regard if the movie could not be played without an associated and distracting unwanted noise accompanying the playing of the movie. As another example, a person attempting to concentrate on tasks in a work environment may find efforts significantly hindered by unwanted noise, whatever its source.

A particularly widespread source of such unwanted noise is noise produced by electrical devices. Many attempts have been made to reduce the noise levels produced by electrical devices. Many such attempts have met with at least some degree of success.

The heat dissipation issues associated with computing devices has lead the vast majority of such devices to include some sort of cooling device. It is often the case that such cooling devices create unwanted noise.

Of course, if the only cooling device implemented by a particular electrical device is a fixed heat sink, no noise would be created. By contrast, cooling fans such as those found in personal computers and notebook computers, as well as other computing devices, are notorious for creating a significant amount of unwanted noise. However the effectiveness of cooling fans in dissipating heat, as well as their relative inexpensiveness, has caused them to be widely used despite the unwanted noise they produce.

One approach to reducing the noise produced by cooling fans has been to specially shape rotors of the cooling fan in order to reduce unwanted noise produced as the rotor generates air flow. Another approach has been to adopt specially shaped stationary frame blades to reduce the amount of unwanted noise created by air flow passing around such frame blades. A third approach to reducing the unwanted noise produced by cooling fans has been to operate such cooling fans submaximally. By reducing the speed of the fan, the amount of noise created by rotor creation of air flow and by air flow around frame blades is reduced. Despite these improvements, a substantial amount of unwanted noise is still created by cooling fans.

Similarly, the use of cooling blowers to dissipate heat from computing devices is associated with generation of a significant amount of unwanted noise. One approach to reduction of such unwanted noise has been to adopt specially shaped air paths. Such a specially air path results in generation of less noise associated with such air flow. Likewise, as with cooling fans, another approach has been to operate cooling blowers at submaximal blower speed in order to reduce the amount of unwanted noise produced by such blowers. However a substantial amount of unwanted noise is still produced by cooling blowers.

Another class of electrical devices which generate unwanted noise is digital video recorders. As discussed above, use of a digital video recorder to play a movie having a quiet scene with soft noises which the viewer desires to hear can be significantly hindered by unwanted noise produced by the digital video recorder itself.

Medical devices would also benefit from reduction of the amount of unwanted noise they produce. For example, a medical device used during surgery that produces a significant amount of associated unwanted noise would naturally tend to hinder the concentration of the surgeon.

While many attempts to reduce unwanted noise produced by electrical devices have been successful, a further reduction of unwanted noise would provide concrete and substantial benefit.

### BRIEF SUMMARY OF THE INVENTION

The present invention achieves a further reduction in the amount of unwanted noise produced by electrical devices by providing an electrical device having pulse width modulation controls for providing a plurality of settings for operation of the device. The electrical device includes a system for selectively controlling the frequency of the pulse width modulation to provide a desired output operational intensity in response to a known input signal. The system includes a high frequency pulse width modulation signal module adapted to provide frequencies above the audible range of anticipated users of the device. By providing frequencies above the audible range of anticipated users, the unwanted noise produced by the electrical device is reduced or eliminated. The high frequency pulse width modulation signal module includes a signal converter. The signal converter receives the known input signal and converts that signal into a high frequency pulse width modulation output signal, which is then used to control the operational intensity of the device. The production of unwanted noise is reduced because the output signal has a frequency above the audible range of anticipated users of such electrical device.

More preferably, the signal converter includes a high frequency signal generator and a comparator module. The high frequency signal generator produces a triangle signal having a frequency above the audible range of anticipated users of the electrical device. The comparator module receives the triangle signal and performs a comparison operation with the triangle signal and the known input signal as input parameters. The comparator module then outputs the high frequency pulse width modulation output signal.

Still more preferably the present invention comprises a personal computing device including a housing, first memory space, second memory space, processor, and cooling device. The first memory space, second memory space and processor are all oriented within the interior of the housing. Whether the first memory space and second memory space are implemented on a single memory device, two memory devices or more than two memory devices is immaterial for purposes of the present invention. The first memory space is suitable for storing program instructions. The second memory space is suitable for storing data. The processor is operatively connected to both memory spaces. The processor is adapted to receive and execute the program instruction of the first memory space. The processor is further adapted to receive data from and send data to the second memory space.

The cooling device is configured to cool the interior of the personal computing device. Operatively, the cooling device has pulse width modulation controls for providing a plurality of settings for operation.

The cooling device includes a system for selectively controlling the frequency of the pulse width modulation to provide a desired output cooling intensity in response to a known input signal. The system includes a high frequency pulse width modulation signal module adapted to provide frequencies above the audible range of anticipated users of such a personal computing device. The signal module includes a signal converter which receives the known input signal and converts that signal to a high frequency pulse width modulation output signal suitable to operate the cooling device at the desired output cooling intensity. Unwanted production of noise is reduced or eliminated because the output signal has a frequency above the audible range for anticipated users of the personal computing device.

These and other advantages of the present invention will be more fully appreciated by the following detailed description of the invention.

### BRIEF DESCRIPTION OF THE DRAWINGS

The following drawings form part of the present specification and are included to further demonstrate certain aspects of the present invention. The figures are not necessarily drawn to scale. The invention may be better understood by reference to one or more of these drawings in combination with the detailed description of specific embodiments presented herein.

FIG. 1 is a schematic depiction of an electrical device of the prior art having its operational intensity directly controlled by a DC input signal.

FIG. 2 is a schematic drawing of an electrical device of the prior art. The operational intensity of the electrical device is controlled by a DC input signal which is converted to a low frequency pulse width modulation signal.

FIG. 3 is a schematic drawing of an electrical device according to the present invention which includes a signal converter for receiving a known input signal and converting that signal to a high frequency pulse width modulation output signal for controlling the operational intensity of the electrical device.

FIG. 4 is a schematic drawing of another electrical device according to the present invention. The figure shows a more preferred implementation of the signal converter.

FIG. 5 is a schematic drawing showing an even more preferred embodiment of an electrical device according to the present invention. In this embodiment, the known input signal is a DC input signal.

FIG. 6 is a schematic drawing that shows the most preferred embodiment of the present invention. The electrical device is shown in the most preferred embodiment to include an operational intensity control circuit, a high frequency signal generator, and a comparator module.

FIG. 7 shows a schematic drawing of an alternative embodiment of the present invention. A high frequency signal converter is included to scale a high frequency triangle signal.

FIG. 8 is a schematic drawing of another alternative embodiment of the present invention including a DC-to-DC converter that scales a DC input signal.

FIG. 9 is a schematic drawing of a further alternative embodiment that includes a low frequency pulse width modulation-to-high frequency pulse width modulation converter.

FIG. 10 is a schematic drawing of yet another embodiment of the present invention. This embodiment includes a low frequency pulse width modulation-to-DC converter and a DC-to-high frequency pulse width modulation converter.

FIG. 11 is a schematic drawing of a still further embodiment of the present invention. This embodiment includes an RC circuit for performing low frequency pulse width modulation-to-DC conversion.

FIG. 12 is a schematic drawing of a further alternative embodiment including a thermistor input and a thermistor signal-to-high frequency pulse width modulation converter.

FIG. 13 is a schematic drawing of an additional alternative embodiment. This embodiment includes a thermistor as well as a high frequency signal generator and a comparator module.

FIG. 14 is a schematic drawing of a personal computing device according to the present invention.

### DETAILED DESCRIPTION OF PREFERRED EMBODIMENTS

It will be understood by those skilled in the art that the present invention can be implemented in a number of different ways, within the scope of the claims appended hereto. A presently preferred embodiment of the invention will now be described below.

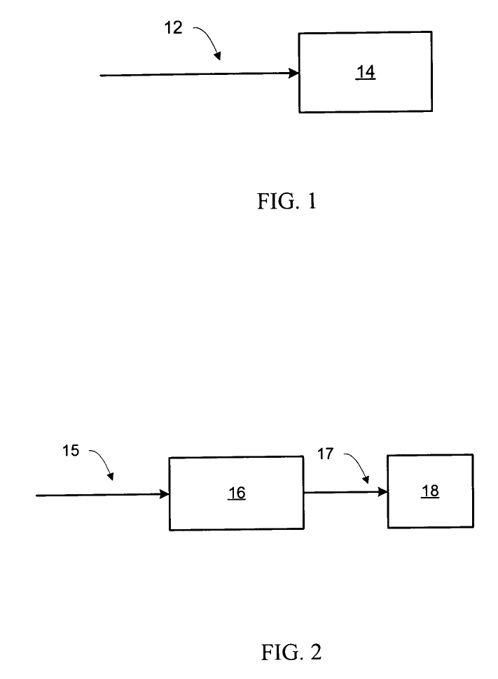

An electrical device 14 of the prior art is shown in FIG. 1. The operational intensity of electrical device 14 is controlled directly by DC input signal 12. Control is achieved by varying the DC input signal level. This approach to controlling operational intensity creates several problems. A significant amount of heat is generated which must be dissipated. Power inefficiencies occur and electronic and microelectronic components tend to be harmed by variation of voltage levels. As adoption of electronic and microelectronic components has become extremely widespread, the increased electronic and microelectronic failure rate associated with using DC input signals to directly control the operational intensity of electrical devices has become a problem.

FIG. 2 shows an approach to solving several of the problems present in the prior art electrical device shown in FIG. 1. A DC-to-low frequency pulse width modulation converter 16 converts DC input signal 15 into low frequency pulse width modulation signal 17 which then controls the operational intensity of electrical device 18.

By definition, pulse width modulation signals are either at 100% or at 0%. Therefore, variation of voltage which has been shown to be harmful to electronic components is avoided. Consider the case where DC input signal 15 can range from 2 volts to 3 volts. If DC input signal 15 is 2.5 volts, the low frequency pulse width modulation signal 17 corresponding to DC input signal 15 will have a 50% duty cycle. That is, the pulse width modulation signal 17 will, over time, will have a value of 1 about 50% of the time and a value of 0 about 50% of the time. Electrical device 18 is controlled to maintain a steady operational intensity by rapid switching of the pulse width modulation signal 17 between 0 and 1. However, if the electrical switching occurs at a speed within the frequency range of human hearing, such switching will produce audible noise. The range of human hearing is usually considered to be about 20 Hz to about 20 kHz. However, women typically have sensitivity to higher frequencies than men. In addition, the maximum audible frequency changes with age, declining at about 1 Hz per day. The upper limit of human hearing for a 15-year old will typically be 20 kHz. Therefore, a 40-year old would typically be expected to have a hearing range of about 11 kHz. A 70-year old would typically be expected to have an upper frequency hearing limit of 2 to 4 kHz.

Moreover, the maximum frequency which a person can hear can be damaged by exposure to high sound levels over extended periods.

It is an important realization that the frequency of a pulse width modulation signal is independent of its duty cycle. Simply stated, the frequency of a pulse width modulation signal is the rate at which the signal switches between 0 and 1. The present invention provides a solution to reducing unwanted noise produced by electrical devices by using high frequency pulse width modulation.

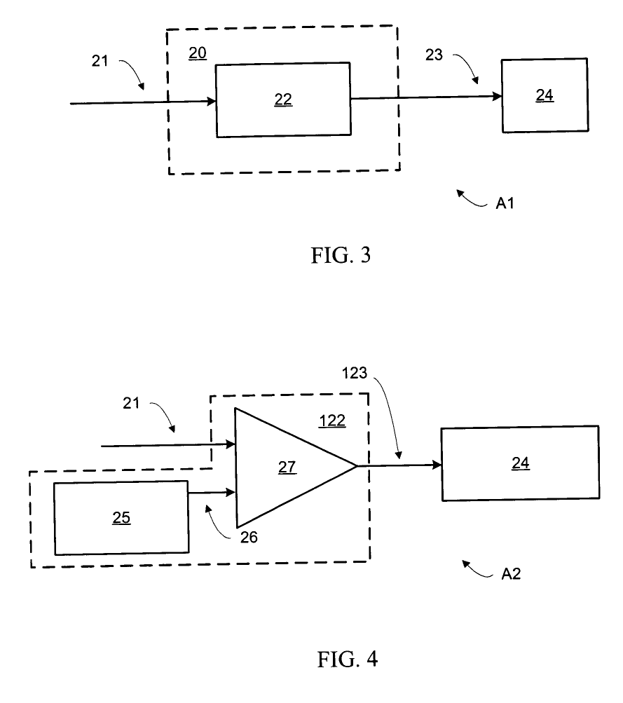

Turning to FIG. 3, a preferred embodiment A1 of the present invention is depicted. The operational intensity of electrical device 24 is ultimately controlled by known input signal 21. System 20 of the preferred embodiment A1 includes a signal converter 22 that converts known input signal 21 into high frequency pulse width modulation output signal 23. The output signal 23 directly controls the operational intensity of electrical device 24. The electrical switching noise that would normally be produced by the pulse width modulation output signal 23 is rendered inaudible by selecting its frequency above the upper limit of anticipated users of the device.

FIG. 4 shows a similar and more preferred embodiment A2. Signal converter 122 receives known input signal 21 and converts the signal 21 into high frequency pulse width modulation output signal 123 in order to control the operational intensity of electrical device 24 without the production of audible noise associated with the electrical switching of the pulse width modulation of output signal 123. Signal converter 122 includes a high frequency signal generator 25. Generator 25 produces a high frequency triangle signal 26 which is sent as an input to comparator module 27. Comparator module 27 also takes as a second input known input signal 21. Module 27 performs a comparison operation on signals 21 and 26 in order to produce output signal 123.

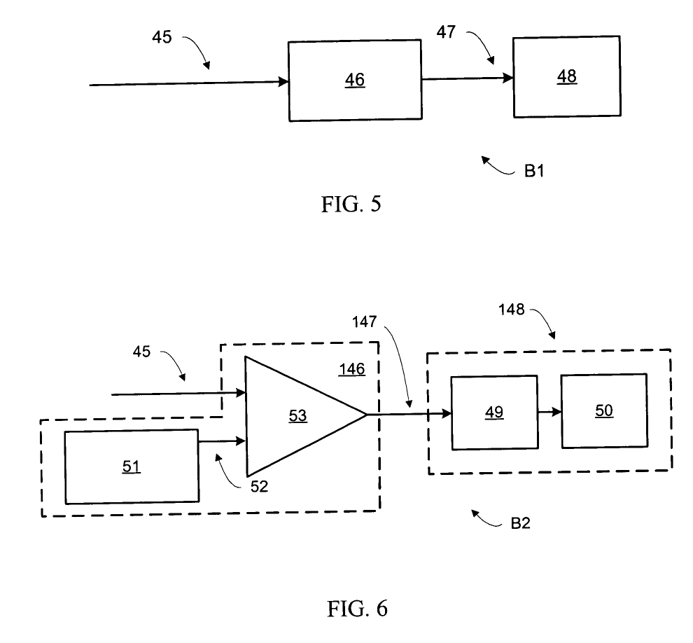

FIGS. 5 and 6 are schematic drawings of embodiments B1 and B2, which are even more preferred. Embodiment B1 includes an electrical device 48 having its operational intensity controlled directly by high frequency pulse width modulation output signal 47. Signal converter 46 produces signal 47 by converting DC input signal 45. Output signal 47 has a frequency set above the range of audible hearing of anticipated users of the device.

Turning to FIG. 6, the most preferred embodiment B2 of the present invention is depicted schematically. Embodiment B2 includes a signal converter 146 and an electrical device 148. Signal converter 146 includes a high frequency signal generator 51, which produces a high frequency triangle signal 52 for input into a comparator module 53. Module 53 performs a comparison operation on DC input signal 45 and input signal 52 in order to produce a high frequency pulse width modulation output signal 147.

The electrical switching inherently required in pulse width modulation output signal 147 is set at a frequency above the range of audible hearing of anticipated users of the device in order to eliminate the unwanted noise that would be produced by a lower frequency pulse width modulation output signal. Electrical device 148 is shown to include an operational intensity control circuit 49 and the remaining portion of electrical device 50. The control circuit 49 receives the output signal 147 and controls the operational intensity of electrical device 148 accordingly.

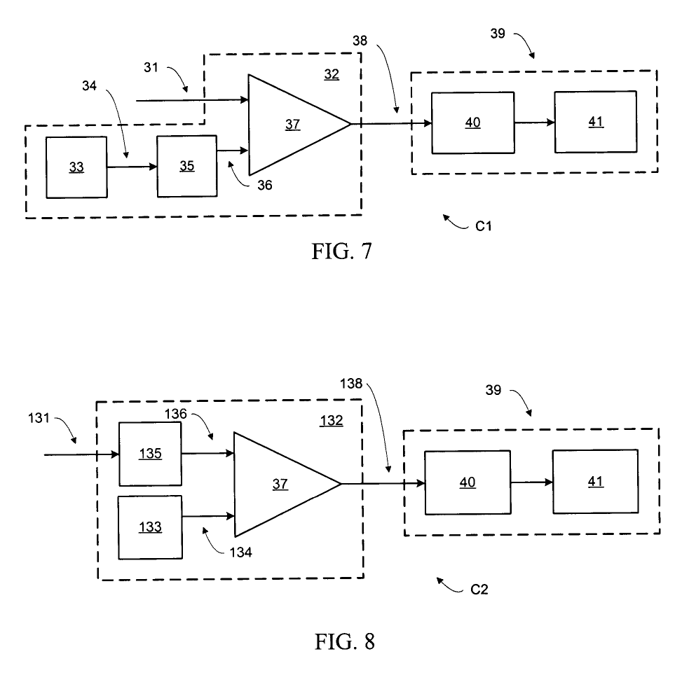

Two alternative embodiments of the present invention are shown in FIGS. 7 and 8 as embodiment C1 and embodiment C2. Alternative embodiment C1 includes a signal converter 32 and an electrical device 39. Signal converter 32 is similar to converter 146, difference being that the high frequency triangle signal 34 which is produced by high frequency signal generator 33 is scaled by high frequency signal converter 35 to produce a scaled high frequency triangle signal 36. The triangle signal 34 is converted by scaling into signal 36 in order to facilitate the comparison operation within module 37 occurring and taking DC input signal 31 as a second input, sending high frequency pulse width modulation output signal 38 to operational intensity control circuit 40 for selectively controlling the operational intensity of the remaining portion 41 of electrical device 39.

Turning to FIG. 8, signal converter 132 is similar to signal converter 146 (shown in FIG. 6). A difference between the converters 132 and 146 is that converter 132 includes a DC-to-DC converter 135 which converts DC input signal 131 into a scaled DC input signal 136. High frequency triangle Signal 134 is produced by high frequency signal generator 133 in order to facilitate the comparison operation performed by comparator module 37, which takes signal 134 as its other argument. The output of module 37 is high frequency output signal 138. Signal 138 is input into operational intensity control circuit 40 which accordingly controls the remaining portion of electrical device 41. Control circuit 40 and remaining portion 41 make up electrical device 39.

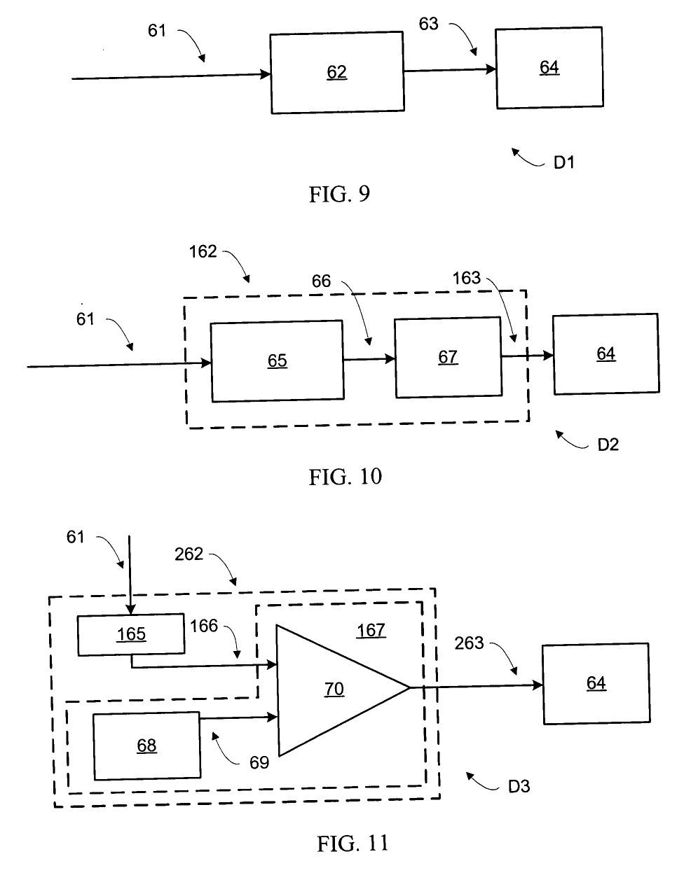

FIGS. 9, 10 and 11 are schematic drawing of further alternative embodiments D1, D2 and D3. FIG. 9 shows an electrical device 64 having its operational intensity controlled ultimately by a low frequency pulse width modulation input signal 61. Signal 61 is converted to a high frequency pulse width modulation output signal 63 by a low frequency pulse width modulation-to-high frequency pulse width modulation converter 62. FIG. 10 includes converter 162 which converts low frequency pulse width modulation input signal 61 into high frequency pulse width modulation output signal 163. Converter 162 includes a low frequency pulse width modulation-to-DC converter 65, which receives as an input signal 61 and produces as its output DC signal 66. Converter 162 also includes a DC-to-high frequency pulse width modulation converter 67 which takes as its input signal 66 and produces as its output signal 163, for controlling the operational intensity of device 64.

Embodiment D3 shown in FIG. 11 is similar to embodiments D1 and D2. Low frequency pulse width modulation input signal 61 ultimately controls the operational intensity of electrical device 64. Converter 262 includes a low frequency pulse width modulation-to-DC converter comprising an RC circuit 165. Circuit 165 converts signal 61 into DC input signal 166. Converter 262 also includes converter 167 which takes as its input DC input signal 166 and produces as its output high frequency pulse width modulation output signal 263. Converter 167 includes a high frequency signal generator 68 and a comparator module 70. Generator 68 produces a high frequency triangle signal 69 as its output. Module 70 takes signal 69 as its input, as well as signal 166, and performs a comparison operation thereon, producing high frequency pulse width modulation output signal 263. Electrical device 64 takes output signal 263 as its input which controls its operational intensity.

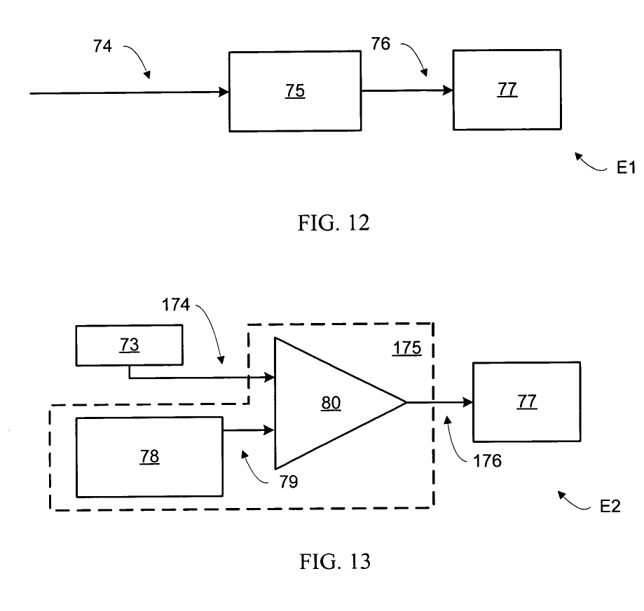

While several alternatives to the preferred embodiments have been discussed, including various examples of known input signals, a great many types of known input signals are encompassed within the spirit and scope of the invention as appreciated by those skilled in the art. For example, FIGS. 12 and 13 are schematic drawings which show other alternative embodiments E1 and E2. Embodiment E1 includes a signal converter that comprises a thermistor signal-to-high frequency pulse width modulation converter 75. Converter 75 takes thermistor input signal 74 as its input and produces corresponding high frequency pulse width modulation output signal 76 as its output. Electrical device 77 takes signal 76 as its input which thereby controls the operational intensity of device 77.

Embodiment E2 includes thermistor 73 signal converter 175 and electrical device 77. Converter 175 includes a high frequency signal generator 78 and a comparator module 80. Generator 78 produces a high frequency triangle signal 79 which is taken as one input of module 80. Thermistor 73 produces a DC input signal 174 which is taken as another input of module 80. Module 80 performs a comparison operation on signal 174 and signal 79, producing corresponding high frequency pulse width modulation output signal 176. Device 77 takes signal 176 as its input which thereby controls the operational intensity of device 77.

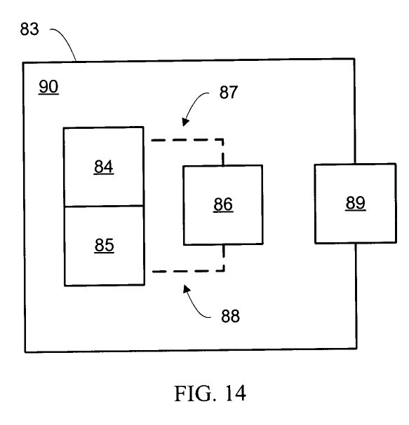

FIG. 14 is a schematic illustration of a personal computing device according to the present invention. The personal computing device includes housing 83 which defines an interior 90 of the personal computing device. The personal computing device also includes a first memory space 84, a second memory space 85, a processor 86 and a cooling device 89. Memory spaces 84 and 85 and processor 86 are oriented within interior 90. It is immaterial for purposes of the present invention whether memory spaces 84 and 85 are implemented on a single memory device, on two memory devices, or on more than two memory devices. First memory space 84 is adapted to store program instructions. Second memory space 85 is adapted to store data. Processor 86 is operatively connected to first memory space 84 by operative connection 87. Processor 86 is also operatively connected to second memory space 85 by operative connection 88. Processor 86 is adapted to read program instructions from memory space 84 and to execute such instructions. Processor 86 is also adapted to receive data from memory space 85 and to send data to memory space 85. Cooling device 89 is configured to cool the interior 90 of housing 83. The operational intensity of cooling device 89 is controlled by a high frequency pulse width modulation signal. The frequency of the signal is selectively set sufficiently high as to be above the upper audible limit of the frequency range of hearing of anticipated users of the personal computing device 82. Cooling device 82 is shown as being framed within the structure of on wall of housing 83. However, as in the other variations and modifications that will be appreciated by those of skill in the art and encompassed within the spirit and scope of the claims, cooling devices 82 may be oriented in any relationship to the housing 83 suitable to allow cooling device to cool interior 90.

The phrase “electrical device” is used herein to indicate any device having an operational intensity that may be controlled by a pulse width modulation signal.

Any element in a claim that does not explicitly state “means for” performing a specified function, or “step for” performing a specific function, is not to be interpreted as a “means” or “step” clause as specified in 35 U.S.C. § 112, ±6. In particular, the use of “step of” in the claims herein is not intended to invoke the provision of 35 U.S.C. § 112, ¶6.

It should be apparent from the foregoing that an invention having significant advantages has been provided. While the invention is shown in only a few of its forms, it will be understood by those skilled in the art that it is not limited to only those embodiments but is susceptible to various changes and modifications without departing from the spirit and scope of the invention. For example, the electrical device could include additional controls by which the upper limit of the audible range for anticipated users could be selectively set in order to flexibly accommodate users having different audible range upper limits. Additionally, multiple electrical devices could be controlled by branching a high frequency pulse width modulation output signal to provide as an input into each of the electrical devices. These and other changes and modifications will be apparent to those skilled in the art in view of the above disclosure and are within the spirit and scope of the invention.

By way of further example of variations falling within the spirit and scope of the invention, use of the word “connect” or any of its derivatives in this specification and in the appended claims implies not only a direct, immediate connection between two recited parts, but also embraces the various arrangements wherein the parts are operatively connected, although other elements may be physically located or eliminated between the connected parts. Similarly, the word “a” does not preclude the presence of a plurality of elements accomplishing the same function. Additionally, use of the words “send,” “receive,” or any of their derivatives in this specification and in the appended claims implies not only a direct, immediate transmission between two elements, but also embraces the various arrangements wherein the transmission operatively occurs, although other elements may intervene in the transmission, or the transmission between two elements may otherwise occur indirectly.

1-15. (Canceled)

16. A personal computing device, comprising:
a housing defining an interior of such personal computing device;
a first memory space oriented within the interior of such personal computing device, suitable for storing program instructions;
a second memory space oriented within the interior of such personal computing device, suitable for storing data;
a processor operably connected to the first memory space and to the second memory space, the processor adapted to receive and execute the program instructions of the first memory space and adapted to receive data from and send data to the second memory space;
a cooling device configured to cool the interior of such personal computing device, having pulse width modulation controls for providing a plurality of settings for operation of the device, including:
a system for selectively controlling the frequency of the pulse width modulation to provide a desired output cooling intensity in response to a known input signal, the system including a high frequency pulse width modulation signal module adapted to provide frequencies above the audible range of anticipated users of such personal computing device, the module including a signal converter operably connectable to such a known input signal and adapted to convert such an input signal to produce a high frequency pulse width modulation output signal suitable for operating such cooling device at the desired output cooling intensity, wherein the output signal has a frequency above the audible range for anticipated users of such a personal computing device.

17. The personal computing device of claim 16, wherein the cooling device comprises a fan and wherein the cooling intensity comprises the speed of the fan rotors in order that the speed of the fan rotors correspond to such a setting for operation of the device based on the known input signal.

18. The personal computing device of claim 16, wherein the cooling device comprises a blower and wherein the cooling intensity comprises the air output rate of the blower in order that the speed of the fan rotors correspond to such a setting for operation of the device based on the known input signal.

19. A cooling fan for reducing otherwise affecting the temperature of a computing device, the cooling fan having pulse width modulation controls for providing a plurality of settings for operation of the fan, thereby controlling fan speed, comprising:
a system for selectively controlling the frequency of the pulse width modulation to provide a desired output operational intensity in response to a known input signal, the system including a high frequency pulse width modulation signal module adapted to provide frequencies above the audible range of anticipated users of the cooling fan, the module including a signal converter operably connectable to the known input signal and adapted to convert the input signal to produce a high frequency pulse width modulation output signal suitable for operating the cooling fan at the desired output operational intensity, wherein the output signal has a frequency above the audible range for anticipated users of the cooling fan.

20. The cooling fan of claim 19, wherein the signal converter comprises:
a high frequency signal generator adapted to produce a high frequency triangle signal having a frequency above the audible range for anticipated users of the cooling fan; and
a comparator module adapted to receive the known input signal and the high frequency triangle signal and perform a comparison operation on the signals in order to produce the high frequency pulse width modulation output signal suitable for operating the cooling fan at the desired output operational intensity, wherein the output signal has a frequency above the audible range for anticipated users of the cooling fan.

21. The cooling fan of claim 19, wherein the known input signal comprises a DC voltage signal for causing the system to provide the desired output operational intensity.

22. The cooling fan of claim 19, wherein the known input signal comprises a low frequency pulse width modulation signal having a frequency within the audible range for anticipated users of such an electrical device for causing the system to provide the desired output operational intensity.

23. The cooling fan of claim 19, wherein the output signal has a frequency of at least 25 kHz, thereby being above the audible range for anticipated users of the cooling fan.

24. The cooling fan of claim 20, wherein the triangle signal has a frequency of at least 25 kHz in order to cause the high frequency pulse width modulation output signal to be above the audible range for anticipated users of the cooling fan.

25. The cooling fan of claim 20, wherein the comparator module comprises a comparator module adapted to receive the known input signal and the triangle signal, convert the known input signal by scaling in order to ensure that the ranges of the known input signal and triangle signal are substantially equivalent to facilitate operation of the cooling fan at the desired operational intensity, and perform a comparison operation on the signals in order to produce the high frequency pulse width modulation output signal suitable for operating the cooling fan at such a desired output operational intensity, wherein the output signal has a frequency above the audible range for anticipated users of the cooling fan.

26. The cooling fan of claim 20, wherein the comparator module comprises a comparator module adapted to receive the known input signal and the triangle signal, convert the triangle signal by scaling in order to ensure that the ranges of the known input signal and triangle signal are substantially equivalent to facilitate operation of the cooling fan at the desired operational intensity, and perform a comparison operation on the signals in order to produce the high frequency pulse width modulation output signal suitable for operating the cooling fan at such a desired output operational intensity, wherein the output signal has a frequency above the audible range for anticipated users of the cooling fan.

27. The cooling fan of claim 20, wherein the comparator module comprises a comparator module adapted to receive the known input signal and the triangle signal, convert the known input signal and the triangle signal by scaling in order to ensure that the ranges of the known input signal and triangle signal are substantially equivalent to facilitate operation of the cooling fan at the desired operational intensity, and perform a comparison operation on the signals in order to produce the high frequency pulse width modulation output signal suitable for operating the cooling fan at such a desired output operational intensity, wherein the output signal has a frequency above the audible range for anticipated users of the cooling fan.

28. The cooling fan of claim 22, wherein the signal converter comprises an RC circuit for converting the low frequency pulse width modulation signal into a DC voltage signal for causing the system to provide the desired output operational intensity, the DC voltage signal corresponding to the low frequency pulse width modulation signal, wherein the signal converter is adapted to convert such a DC voltage signal to produce a high frequency pulse width modulation output signal suitable for operating the cooling fan at the desired output operational intensity, wherein the output signal has a frequency above the audible range for anticipated users of the cooling fan

29. The cooling fan of claim 21, further comprising a thermistor adapted to detect a temperature and produce the DC voltage signal at a voltage level corresponding to the detected temperature in order to perform such operation of the cooling fan at an operational intensity correlated to the detected temperature.

30. An electrical device having pulse width modulation controls for providing a plurality of settings for operation of the device, thereby controlling operational intensity, comprising:
a system for selectively controlling the frequency of the pulse width modulation to provide a desired output operational intensity in response to a known input signal, the system including a high frequency pulse width modulation signal module adapted to provide frequencies above the audible range of anticipated users of such electrical device, the module including a signal converter operably connectable to such a known input signal and adapted to convert such an input signal to produce a high frequency pulse width modulation output signal suitable for operating such electrical device at the desired output operational intensity, wherein the output signal has a frequency above the audible range for anticipated users of such an electrical device.

31. The device of claim 30, wherein such device is a blower having pulse width modulation controls for providing a plurality of settings for operation, wherein the frequency of the pulse width modulation is selectively controlled by the system to provide the desired output operational intensity in response to the known input signal.

32. The device of claim 30, wherein such device is a medical device having pulse width modulation controls for providing a plurality of settings for operation, wherein the frequency of the pulse width modulation is selectively controlled by the system to provide the desired output operational intensity in response to the known input signal.

33. The device of claim 30, wherein such device is a digital video recorder having pulse width modulation controls for providing a plurality of settings for operation, wherein the frequency of the pulse width modulation is selectively controlled by the system to provide the desired output operational intensity in response to the known input signal.
